(19) United States
(12) Patent Application Publication
(10) Pub. No.: US 2015/0068578 A1
(43) Pub. Date: Mar. 12, 2015

(54) method for manufacturing thin-film solar modules, and thin-film solar modules which are obtainable according to this method

(71) Applicant: ROBERT BOSCH GMBH, Stuttgart (DE)

(72) Inventor: Volker Probst, Berlin (DE)

(73) Assignee: Robert Bosch GmbH, Stuttgart (DE)

(21) Appl. No.: 14/389,208

(22) PCT Filed: Feb. 15, 2013
(86) PCT No.: PCT/EP2013/053111

§ 371 Date: Sep. 29, 2014

(30) Foreign Application Priority Data
Apr. 2, 2012 (DE) 102012205378.6

(51) Int. Cl. H01L 31/18; H01L 31/0224

(52) U.S. Cl. CPC H01L 31/186; H01L 31/1884; H01L 31/18; H01L 31/022425
USPC 136/244; 438/80

(57) ABSTRACT

A method for manufacturing photovoltaic thin-film solar modules, including: applying a back electrode layer to a substrate, applying at least one conductive barrier layer, applying at least one contact layer, applying at least one kesterite or chalcopyrite semiconductor absorber layer, applying at least one buffer layer, removing the applied layers with laser treatment with formation of first separating trenches, filling the first separating trenches using at least one insulating material, removing layers extending from the barrier layer in the direction of the semiconductor absorber layer with formation of second separating trenches, or chemical phase transformation or thermal decomposition of layers extending from the barrier layer in the direction of the semiconductor absorber layer with the formation of first linear conductive areas, applying at least one transparent front electrode layer with filling and contacting of the second separating trenches or with contacting of the first linear conductive areas, so that adjacent solar cells are series connected, and removing the layers extending from the barrier layer in the direction of the front electrode layer with formation of third separating trenches. Described are such modules obtained by the method.

### FIELD OF THE INVENTION

The present invention relates to a method for manufacturing photovoltaic thin-film solar modules, and the thin-film solar modules which are obtainable according to this method.

### BACKGROUND INFORMATION

Photovoltaic thin-film solar modules are believed to have been understood and also commercially available. These types of modules may generally be based on the use of a so-called chalcopyrite semiconductor absorber layer, such as a Cu(In,Ga)(Se,S) system, and represent a complex multilayer system. The manufacture of such thin-film solar modules is a multistep process in which, due to numerous interactions, each method stage must be carefully coordinated with subsequent method stages. Due to plant engineering constraints, it is often extremely difficult or impossible to manufacture thin-film solar modules on a large scale having a module format with a size greater than 1.2 m×0.5 m. In addition, for the temperatures and reaction conditions to be used in the individual manufacturing stages, it has not been possible thus far to exclude contamination or interdiffusion of components, dopants, or impurities of individual layers of the multilayer system.

It would therefore be desirable to be able to rely on a method for manufacturing photovoltaic thin-film solar modules which does not have the disadvantages of the related art, and which in particular manages with fewer process steps and at the same time is not subject to restrictions, such as with regard to module formats, as is known from the methods of the related art.

### SUMMARY OF THE INVENTION

A method for manufacturing photovoltaic thin-film solar modules, including: applying a back electrode layer to a substrate, applying at least one conductive barrier layer, applying at least one contact layer, applying at least one kesterite or chalcopyrite semiconductor absorber layer, applying at least one buffer layer, removing the applied layers with laser treatment with the formation of first separating trenches, filling the first separating trenches using at least one insulating material, removing those layers extending from the barrier layer in the direction of the semiconductor absorber layer with the formation of second separating trenches, or chemical phase transformation or thermal decomposition of those layers extending from the barrier layer in the direction of the semiconductor absorber layer with the formation of first linear conductive areas, applying at least one transparent front electrode layer with filling and contacting of the second separating trenches or with contacting of the first linear conductive areas, so that adjacent solar cells are connected in series, and removing the layers extending from the barrier layer in the direction of the front electrode layer with the formation of third separating trenches. Also described are photovoltaic thin-film solar modules obtained by the foregoing method.

In particular, a method has been found for manufacturing photovoltaic thin-film solar modules which includes the following steps:
providing an in particular planar substrate,
applying at least one back electrode layer to the substrate,
applying at least one conductive barrier layer,
applying at least one, in particular ohmic, contact layer,
applying at least one, in particular kesterite or chalcopyrite, semiconductor absorber layer,
optionally applying at least one first buffer layer,
optionally applying at least one second buffer layer,
a first structuring step which includes removing the applied layers along spaced-apart lines with the aid of laser treatment (first laser treatment), with formation of first separating trenches which separate adjacent solar cells,
filling the first separating trenches with at least one insulating material,
a second structuring step which includes
   removing those layers which extend from the barrier layer in the direction of the semiconductor absorber layer or buffer layer(s) along spaced-apart lines, with formation of second separating trenches which are adjacent to corresponding first separating trenches or which abut on same, in particular which extend in parallel to same,
or
   chemical phase transformation or thermal decomposition of those layers which extend from the barrier layer in the direction of the semiconductor absorber layer or buffer layer(s) along spaced-apart lines, with formation of first linear conductive areas,
applying at least one transparent front electrode layer with filling and contacting of the second separating trenches or with contacting of the first linear conductive areas so that adjacent solar cells are connected in series, and
at least one third structuring step which includes removing the layers which extend from the barrier layer in the direction of the at least one front electrode layer along spaced-apart lines, with formation of third separating trenches which are adjacent to corresponding second separating trenches or which abut on same, in particular which extend in parallel to same.

The substrate may be transparent, at least in part, to electromagnetic radiation of the first laser treatment. Suitable substrates include, for example, glass substrates such as glass plates. Alternatively, flexible and nonflexible plastic layers, such as plastic films or stainless steel layers, may be used.

In one suitable embodiment of the method according to the present invention, it is provided that the back electrode contains or is formed essentially from tungsten, chromium, tantalum, niobium, vanadium, manganese, titanium, zirconium, cobalt, and/or molybdenum, which may be tungsten, titanium, and/or molybdenum, or from an alloy containing tungsten, chromium, tantalum, niobium, vanadium, manganese, titanium, zirconium, cobalt, iron, nickel, aluminum, and/or molybdenum. Within the meaning of the present invention, the back electrode may also be referred to as a bulk back electrode, and the system made up of the bulk back electrode, barrier layer, and contact layer may be referred to as a multilayer back electrode. In one embodiment, it may be provided that the bulk back electrode and the contact layer contain molybdenum or tungsten or a molybdenum alloy or a tungsten alloy, in particular molybdenum or a molybdenum alloy, or are formed essentially from molybdenum or tungsten or a molybdenum alloy or a tungsten alloy, in particular molybdenum or a molybdenum alloy.

In the method according to the present invention, embodiments may also be used in particular in which the conductive barrier layer represents a barrier layer which acts bidirectionally, in particular a barrier for in particular diffusing or diffusable components, in particular dopants, which migrate out of and/or through the back electrode layer, and for diffusing or diffusable components, in particular dopants, which migrate out of and/or through the contact layer, in particular out of the semiconductor absorber layer. It is provided in particular that the barrier layer represents a barrier against alkali ions, in particular sodium ions, selenium or selenium compounds, sulfur or sulfur compounds, and/or metals, in particular iron, nickel, and/or metals of the semiconductor absorber layer, for example against Cu, In, Ga, Fe, Ni, Al, Ti, Zr, Hf, V, Nb, Ta, and/or W. The barrier layer may contain or is formed essentially from at least one metal nitride, at least one metal silicon nitride, at least one metal carbide, and/or at least one metal boride. The metal of the metal nitrides, metal silicon nitrides, metal carbides, and/or metal borides may represent titanium, molybdenum, tantalum, zirconium, or tungsten. The barrier layer particularly may contain or is formed essentially from TiN, TiSiN, MoN, TaSiN, MoSiN, TaN, WN, ZrN, and/or WSiN.

As a bidirectionally acting barrier layer, the conductive barrier layer represents a barrier for in particular diffusing or diffusable components, in particular dopants, which migrate out of and/or through the back electrode layer, and for diffusing or diffusable components, in particular dopants, which migrate out of and/or through the contact layer, in particular out of the semiconductor absorber layer. Due to the presence of a barrier layer it is possible, for example, to significantly reduce the degree of purity of the bulk back electrode material. For example, the bulk back electrode layer may have impurities of at least one element selected from the group composed of Fe, Ni, Al, Cr, Ti, Zr, Hf, V, Nb, Ta, W, and/or Na and/or compounds of the mentioned elements without adversely affecting the efficiency of the thin-film solar cell or module which includes the back electrode according to the present invention.

Metal nitrides of this type, such as TiN, may be used as barrier materials within the meaning of the present invention, in which the metal is deposited stoichiometrically or hyperstoichiometrically with respect to nitrogen, i.e., with an excess of nitrogen.

Another advantage of using a barrier layer with the multilayer back electrodes according to the present invention when used in thin-film solar cells and modules is that the thickness of the semiconductor absorber layer, the chalcopyrite or kesterite layer, for example, may be markedly reduced compared to a conventional system. Due to the presence of the barrier layer, in particular when in the form of metal nitrides such as titanium nitride or containing such metal nitrides or titanium nitrides, the sunlight passing through the semiconductor absorber layer is reflected very effectively, so that a very good quantum yield may be achieved in the course of the double passage through the semiconductor absorber layer. Due to the presence of the mentioned barrier layer in the back electrode according to the present invention or in thin-film solar cells or modules containing this back electrode, the average thickness of the semiconductor absorber layer may be reduced, for example, to values in the range of 0.4 μm to 1.5 μm, for example to values in the range of 0.5 μm to 1.2 μm.

In one particularly advantageous embodiment, the barrier layer of the back electrode according to the present invention has barrier properties, in particular bidirectional barrier properties, with respect to dopants, in particular with respect to dopants for the semiconductor absorber layer and/or from the semiconductor absorber layer, with respect to chalcogens such as selenium and/or sulfur as well as chalcogen compounds, with respect to the metallic components of the semiconductor absorber layer, such as Cu, In, Ga, Sn, and/or Zn, with respect to impurities such as iron and/or nickel from the bulk back electrode layer, and/or with respect to components and/or impurities from the substrate. The bidirectional barrier properties with respect to dopants from the substrate should on the one hand prevent enrichment with alkali ions, diffusing from a glass substrate, for example, at the interface of the back electrode or contact layer with respect to the semiconductor absorber layer. Such enrichment is known as one reason for semiconductor layer delamination. The conductive barrier layer is thus intended to help avoid adhesion problems. On the other hand, the barrier property for dopants which are diffusable or diffusing from the semiconductor absorber should prevent dopant thus being lost at the bulk back electrode and thus depleting the semiconductor absorber of dopant, which would greatly reduce the efficiency of the solar cell or the solar module. It is known, for example, that molybdenum back electrodes are able to absorb significant quantities of sodium dopant. The bidirectional conductive barrier layer should thus allow the requirements to be met for a targeted dosing of dopant into the semiconductor absorber layer, in order to be able to achieve reproducibly high efficiencies of the solar cells and modules.

The barrier property with respect to chalcogens should prevent the chalcogens from reaching the back electrode and forming metal chalcogenide compounds there. It is known that these chalcogenide compounds, such as MoSe, contribute to a significant increase in volume of the layer of the back electrode near the surface, which in turn results in unevennesses in the layer structure and impaired adhesion. Impurities such as Fe and Ni in the bulk back electrode material represent so-called deep imperfections for chalcopyrite semiconductors, for example (semiconductor poisons), and therefore must be kept away from the semiconductor absorber layer via the barrier layer.

In one advantageous embodiment, the barrier layer typically has an average thickness of at least 10 nm, in particular at least 30 nm, and which may be 250 nm or 150 nm maximum.

The contact layer may directly adjoin the barrier layer on the side facing the substrate and/or directly adjoins the semiconductor absorber layer on the side facing the front electrode. The contact layer suitably contains at least one metal chalcogenide. The metal of the metal chalcogenide is advantageously selected from the group composed of molybdenum, tungsten, tantalum, cobalt, zirconium, and/or niobium, and/or the chalcogen is selected from the group composed of selenium and/or sulfur. One advantageous embodiment of the method according to the present invention provides that the contact layer contains or is formed essentially from molybdenum, tantalum, zirconium, cobalt, niobium, and/or tungsten, and/or at least one metal chalcogenide selected from metal selenide, metal sulfide, and/or metal sulfoselenide, where the metal is Mo, W, Ta, Zr, Co, or Nb, and in particular is selected from the group MoSe₂, WSe₂, TaSe₂, NbSe₂, Mo(Se₁₋ₓ, Sₓ)₂, W(Se₁₋ₓ,Sₓ)₂, Ta(Se₁₋ₓ,Sₓ)₂, and/or Nb(Se₁₋ₓ,Sₓ)₂, where x assumes any arbitrary value from 0 to 1.

Particularly advantageous results are obtained with a method variant in which the contact layer contains at least one dopant for the semiconductor absorber layer of the thin-film solar cell. The dopant may be selected from the group composed of sodium, potassium, and lithium and/or at least one compound of these elements, which may be with oxygen, selenium, sulfur, boron, and/or halogens such as iodine or fluorine, and/or contains at least one alkali metal bronze, in particular sodium bronze and/or potassium bronze, which may be with a metal selected from molybdenum, tungsten, tantalum, and/or niobium.

In addition, the contact layer usually has an average thickness of at least 5 nm and may be not greater than 150 nm, particularly not greater than 50 nm.

Furthermore, it is advantageously provided that the semiconductor absorber layer represents or includes a quaternary IB-IIIA-VIA chalcopyrite layer, in particular a Cu(In,Ga)Se₂-layer, a pentenary IB-IIIA-VIA chalcopyrite layer, in particular a Cu(In,Ga)(Se₁₋ₓ,Sₓ)₂-layer, or a kesterite layer, in particular a Cu₂ZnSn(Seₓ,S₁₋ₓ)₄-layer, such as a Cu₂ZnSn(Se)₄-layer or a Cu₂ZnSn(S)₄-layer, where x assumes any arbitrary value from 0 to 1. The kesterite layers are generally based on a IB-IIA-IVA-VIA structure. Cu₂ZnSnSe₄ and Cu₂ZnSnS₄ are named as examples. In one method variant it may be provided that metals which are present in the contact layer or which form this contact layer are completely or partially converted into metal selenides, metal sulfides, and/or metal sulfoselenides by applying the kesterite or chalcopyrite semiconductor absorber layer to the contact layer.

The method according to the present invention may also be carried out in such a way that the contact layer includes a layer sequence composed of at least one metal layer and at least one metal chalcogenide layer, the metal layer adjoining or abutting on the back electrode layer or the conductive barrier layer, and the metal chalcogenide layer adjoining or abutting on the semiconductor absorber layer. In addition, approaches in which the metal layer and the metal of the metal chalcogenide layer are the same, in particular which represent molybdenum and/or tungsten, are advantageous.

Another embodiment of the method according to the present invention provides that at least one first metal ply made of molybdenum, tantalum, zirconium, cobalt, tungsten, and/or niobium, for example, is applied to the barrier layer, and that during the production of the semiconductor absorber layer, in particular the kesterite or chalcopyrite semiconductor absorber layer, this first metal ply is partially converted into a metal chalcogenide layer in a selenium- and/or sulfur-containing atmosphere, with formation of the contact layer.

Another embodiment of the method according to the present invention further provides that at least one first metal ply made of molybdenum, tantalum, tungsten, cobalt, zirconium, and/or niobium is applied to the barrier layer, and that during the production of the semiconductor absorber layer, in particular the kesterite or chalcopyrite semiconductor absorber layer, this first metal ply is completely converted into a metal chalcogenide layer in a selenium- and/or sulfur-containing atmosphere, with formation of the contact layer.

In the method according to the present invention, in one suitable embodiment the step of applying the semiconductor absorber layer, in particular the kesterite or chalcopyrite semiconductor absorber layer, includes the following: depositing in particular all metallic components of the semiconductor absorber layer, in particular copper, indium, and optionally gallium, for the chalcopyrite semiconductor absorber layer, and copper, zinc, and tin for the kesterite semiconductor absorber layer, on the contact layer with formation of a second metal ply, and treating this second metal ply with selenium and/or a selenium compound and optionally with sulfur and/or a sulfur compound, which may be at temperatures above 300° C., in particular above 350° C.

It may also be provided, among other things, that the coated substrate is separated, in particular cut, into multiple individual modules prior to the treatment of the second metal ply, in particular the copper/indium or copper/indium/gallium metal ply or the copper/zinc/tin metal ply, with selenium and/or a selenium compound and optionally with sulfur and/or a sulfur compound.

The first and/or second metal ply is/may be obtained with the aid of physical gas phase deposition, in particular including physical vapor deposition (PVD) coating, vapor deposition with the aid of an electron beam evaporator, vapor deposition with the aid of a resistance evaporator, induction evaporation, ARC evaporation, and/or cathode sputtering (sputter coating), in particular DC or RF magnetron sputtering, in each case may be in a high vacuum, or with the aid of chemical gas phase deposition, in particular including chemical vapor deposition (CVD), low pressure CVD, and/or atmospheric pressure CVD.

A method variant is also advantageous in which the application of the back electrode layer, the conductive barrier layer, the contact layer, and the metals of the semiconductor absorber layer, in particular Cu, In, and Ga layers for forming the chalcopyrite semiconductor absorber layer, or Cu, Zn, and Sn layers for forming the kesterite semiconductor absorber layer, takes place in particular in a single vacuum coating unit, which may be in the continuous sputtering process.

The first buffer layer may be deposited dry or also by wet chemical methods. The first buffer layer may contain or be formed essentially from CdS or a CdS-free layer, in particular containing or composed essentially of Zn(S,OH) or In₂S₃. The second buffer layer may contain or is formed essentially from intrinsically conductive zinc oxide and/or high-resistance zinc oxide.

The material used for the front electrode may be transparent to electromagnetic radiation, in particular to radiation having a wavelength in the range of the absorption wavelength range of the semiconductor. Suitable front electrode materials for photovoltaic thin-film solar cells and their application are known to those skilled in the art. In one specific embodiment, the front electrode contains or is formed essentially from n-doped zinc oxide.

In the method according to the present invention, the first laser treatment, the second laser treatment, and/or the third laser treatment is/are advantageously carried out using laser light pulses having a pulse duration of less than 10 nanoseconds, in particular less than 100 picoseconds. In one advantageous embodiment, the second laser treatment may be carried out from the side facing the buffer layer.

In one suitable embodiment, it is provided that in the second and/or third structuring step, the second or third separating trenches and the chemical phase transformation, in particular by thermal decomposition, of those layers which extend from the barrier layer in the direction of the semiconductor absorber layer or buffer layer(s) are produced with the aid of laser treatment. The laser treatment in the first structuring step, in particular by laser ablation, which may be takes place from the side facing away from the coated side of the substrate. In one specific embodiment, the third separating trenches may be formed in the third structuring step with the aid of mechanical structuring, in particular needle scoring, and/or with the aid of a third laser treatment.

In one practical embodiment, it is provided that at least one second separating trench, in particular all second separating trenches, is/are present in each case adjacent to and at a distance from a filled first separating trench. In addition, it may be provided that at least one third separating trench, in particular all third separating trenches, is/are separated from the corresponding filled first separating trench via the corresponding filled second separating trench or first linear conductive area.

Furthermore, the method according to the present invention provides that the first, second, and third structuring steps result in or contribute to a monolithically integrated series connection of the solar cells, and in particular are configured as line-forming, i.e., separating trench-forming, processing steps.

In addition, in another embodiment the first, second, and/or third separating trench has/have an average width of not greater than 30 μm, which may be not greater than 15 μm.

The substrate which is used in the method according to the present invention may represent a plate or film, in particular a glass plate, having a width greater than 0.5 m, in particular greater than 2 m, and particularly greater than 3 m, and a length greater than 1.2 m, in particular greater than 3 m, and may be greater than 5 m. For example, it is even possible to use substrate formats, in particular glass substrate formats, having a width of 3.2 m and a length of 6 m, from which, for example, 16 thin-film solar modules in a 1.6 m×0.7 m module format may be obtained.

Moreover, the object underlying the present invention is achieved by a photovoltaic thin-film solar module which is obtainable according to the method according to the present invention.

Photovoltaic thin-film solar modules obtained by the method according to the present invention may contain, in the following sequence, at least one substrate layer, at least one back electrode layer, at least one conductive barrier layer, at least one in particular ohmic contact layer, at least one semiconductor absorber layer which in particular directly adjoins the contact layer, in particular a chalcopyrite or kesterite semiconductor absorber layer, and at least one front electrode.

It may be provided, among other things, that at least one buffer layer, in particular at least one layer (first buffer layer) which contains or is formed essentially from CdS or a CdS-free layer, in particular which contains or is formed essentially from Zn(S,OH) or In₂S₃, and/or at least one layer (second buffer layer) which contains or is formed essentially from intrinsic zinc oxide and/or high-resistance zinc oxide, is present between the semiconductor absorber layer and the front electrode.

In addition, thin-film solar modules according to the present invention are particularly advantageous when the semiconductor absorber layer represents or includes a quaternary IB-IIIA-VIA chalcopyrite layer, in particular a Cu(In,Ga)Se₂-layer, a pentenary IB-IIIA-VIA chalcopyrite layer, in particular a Cu(In,Ga) (Se₁₋ₓ,Sₓ)₂-layer, or a kesterite layer, in particular a Cu₂ZnSn(Seₓ,S₁₋ₓ)₄-layer, such as a Cu₂ZnSn(Se)₄-layer or a Cu₂ZnSn(S)₄-layer, where x assumes any arbitrary value from 0 to 1.

In addition, one advantageous embodiment of the thin-film solar module according to the present invention provides that the contact layer includes at least one metal layer and at least one metal chalcogenide layer, the metal layer adjoining or abutting on the back electrode or adjoining or abutting on the barrier layer, and the metal chalcogenide layer adjoining or abutting on the semiconductor absorber layer.

The metal layer and the metal chalcogenide layer may be based on the same metal, in particular molybdenum and/or tungsten. The contact layer may represent a metal chalcogenide layer.

It has proven to be advantageous when the dopant, in particular sodium ions, is/are present in the contact layer and/or in the semiconductor absorber layer of the thin-film solar cell or module which includes the back electrode in a dose in the range of 10¹³ to 10¹⁷ atoms/cm², which may be in a dose in the range of 10¹⁴ to 10¹⁶ atoms/cm².

For the case of doping the contact layer with dopants for the semiconductor absorber layer of a thin-film solar cell, the multilayer back electrode according to the present invention has proven to be suitable. Temperatures above 300° C. or above 350° C. are generally used during the production of the semiconductor absorber layer. These temperatures frequently are even in the range of 500° C. to 600° C. At such temperatures, dopants, such as sodium ions or sodium compounds in particular, migrate, in particular diffuse, from the doped contact layer into the semiconductor absorber layer. As a result of the barrier layer, migration or diffusion into the back electrode layer does not take place.

Due to the mentioned relatively high temperatures in the processing of the semiconductor, it is advantageous that the selected layers of the multilayer back electrode, in particular the bulk back electrode and/or the conductive barrier layer, have a composition such that their linear coefficient of thermal expansion is adapted to that of the semiconductor absorber and/or the substrate. Therefore, the composition in particular of the bulk back electrode and/or the barrier layer of the thin-film solar cells and modules according to the present invention may be such that a linear coefficient of thermal expansion of 14*10⁻⁶ K, which may be 9*10⁻⁶ K, is not exceeded.

Within the meaning of the present invention, it may be provided that the average thickness of the bulk back electrode layer is in the range of 50 nm to 500 nm, in particular in the range of 80 nm to 250 nm, and/or the average thickness of the barrier layer is in the range of 10 nm to 250 nm, in particular in the range of 20 nm to 150 nm, and/or the average thickness of the contact layer is in the range of 2 nm to 200 nm, in particular in the range of 5 nm to 100 nm. The overall thickness of the multilayer back electrode may be set in such a way that the overall specific resistance of the back electrode according to the present invention does not exceed 50 microohms*cm, which may be 10 microohms*cm. Under these criteria, ohmic losses in a module connected in series may be even further reduced.

The present invention is based on the surprising finding that, due to the sequence of the structuring processes, in particular in combination with the provided multilayer back electrode, monolithically integrated solar cells connected in series may be obtained in mass production in high quality and with high efficiencies in a cost-efficient and reproducible manner. In manufacturing methods known from the related art, an undesirable reaction with selenium and/or sulfur or with hydrogen selenide and/or hydrogen sulfide takes place at the structuring trench flanks of the separated back electrode. This is because in these known methods, the structuring trenches are produced prior to the semiconductor formation process, for which reason the structuring trenches are under the effect of the high temperatures in the range of 350° C. to 600° C. used in the semiconductor formation, and optionally also alkali diffusion, and then frequently corrode under the effect of selenium or sulfur. This results in layer infiltration and the formation of microcracks due to mechanical stress caused by the volume expansion of the metals which are corroded under the effect of selenium and/or sulfur. These disadvantages are avoided with the method according to the present invention. In one embodiment, the method according to the present invention provides, among other things, for use of a barrier layer for chalcogens such as selenium and/or sulfur and chalcogen compounds, and structuring of the barrier layer in a time sequence only after the reactive semiconductor formation process. Using the method according to the present invention also avoids having to carry out the laser structuring at a molybdenum back electrode, for example, at a point in time at which microcracks as well as melting of the molybdenum at the structuring edge may not be completely avoided. In any event, both phenomena allow at least partial impairment of the thin-film solar cell under the conditions for forming the semiconductor absorber layer. The method according to the present invention also allows the damage to the insulating barrier layer, which otherwise frequently occurs in the laser process, to be avoided. Consequently, alkali ions may be prevented from passing from the substrate glass into the semiconductor absorber layer in an uncontrolled manner. As the result of avoiding overdoping of the semiconductor absorber layer and filling the structuring trench with insulator filling material, the desired high bridge resistance between adjacent cells is greatly improved over the related art, resulting in a significant gain in the filling factor and the efficiency. In addition, the controlled doping of the semiconductor absorber layer ensures that adhesion problems, induced by alkali ions, in the individual layers in the thin-film solar module obtained according to the method according to the present invention no longer occur. The proportion of unusable rejects may thus be drastically reduced.

The method according to the present invention also allows for the first time the use of a conductive barrier layer in combination with the bulk back electrode within the meaning of the present invention for a monolithically integrated series connection of thin-film solar cells in photovoltaic thin-film solar modules. The bulk back electrode according to the present invention, which generally is not resistant to corrosion in a selenium- and sulfur-containing atmosphere, is protected during the semiconductor manufacturing process by the not yet structured or not yet separated barrier layer. Breaking open of the barrier layer and the absorber layer situated thereabove on the structuring trench due to corrosion-related volume expansion of the bulk back electrode layer, typically by a factor of 3, may thus be avoided. The multilayer back electrode is not structured with the semiconductor absorber layer and the buffer layer until after the corrosive semiconductor formation process.

In addition, the method according to the present invention allows the use of materials of lower purity for the bulk back electrode layer, for example. It is thus possible to better coordinate the thermal expansion characteristic of the various material layers of the thin-layer module with one another. This has the positive effect, among others, that delamination phenomena or adhesion problems during the manufacturing process may be curtailed even further.

The present invention is also based on the finding that the disadvantages in the manufacture of thin-film solar modules according to the related art may also be overcome in particular by carrying out the first structuring step only after the application of the buffer layer(s), which may be with the aid of laser treatment. The mentioned advantageous effects also result in particular when the described structuring mode is carried out on such a thin-film solar module or a precursor of a thin-film solar module which is equipped with the above-described barrier layer, in particular a barrier layer which acts bidirectionally.

Also advantageous is the surprising finding that the first and second structuring steps as well as filling the structuring trench with insulating material may be carried out in a single unit, as the result of which shorter line distances of the separating trenches are ultimately possible, which in turn contributes to an increase in the active surface area of the individual solar cell, and thus also contributes to an increased efficiency of the thin-film solar module. For example, very fine-dosing ink jet methods known from the ink jet printing industry are suitable as a method for insulator filling. For example, a quick-curing insulator ink or a UV-curing, electrically insulating lacquer as known from semiconductor technology may be used as filling material. The UV illumination takes place immediately after the filling step. For example, laser light pulses having a pulse duration of less than 10 picoseconds are used in the method for the first and second laser treatments. A line advance with speeds of several m/s is suitable for mass production.

Further features and advantages of the present invention result from the following description, in which specific embodiments of the present invention are explained as an example with reference to schematic drawings.

### BRIEF DESCRIPTION OF THE DRAWINGS

FIG. 1 shows a schematic cross-sectional view of a manufacturing stage of a thin-film solar module according to the present invention in the method according to the present invention.

FIG. 2 shows a schematic cross-sectional view of a subsequent manufacturing stage of a thin-film solar module according to the present invention in the method according to the present invention.

FIG. 3 shows a schematic cross-sectional view of a further manufacturing stage of a thin-film solar module according to the present invention in the method according to the present invention.

FIG. 4 shows a schematic cross-sectional view of a further manufacturing stage of a thin-film solar module according to the present invention in the method according to the present invention.

FIG. 5 shows a schematic cross-sectional view of a further manufacturing stage of a thin-film solar module according to the present invention in the method according to the present invention.

### DETAILED DESCRIPTION

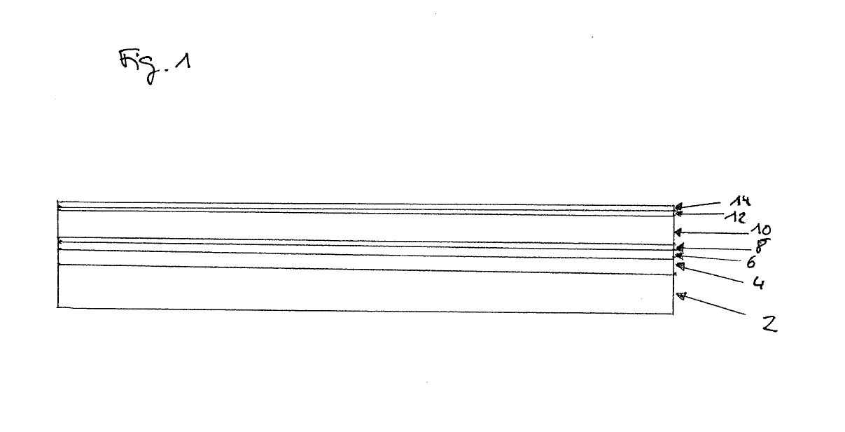

FIG. 1 shows a schematic cross-sectional view of an intermediate manufacturing stage 1a of a thin-film solar module 1 according to the present invention. A bulk back electrode layer 4 made of molybdenum and provided with the aid of thin-film deposition is present on glass substrate 2. The bulk back electrode layer is adjoined by a bidirectional reflective barrier layer 6 made of TiN or ZrN, for example, which likewise may be obtained with the aid of thin-film deposition. In the illustrated specific embodiment, an ohmic contact layer 8 made of a metal chalcogenide such as molybdenum selenide is situated on barrier layer 6. This contact layer may be obtained in various ways. In one embodiment, for example, molybdenum selenide from a molybdenum selenide target has been sputtered on. Alternatively, initially a metal layer may be applied which is subsequently converted into the corresponding metal chalcogenide before and/or during the formation of the semiconductor absorber layer. In one specific embodiment, contact layer 8 may also be combined with at least one dopant such as sodium ions or a sodium compound, in particular sodium sulfite or sodium sulfide. Layer 10 represents the semiconductor absorber layer, and may be present, for example, as a chalcopyrite semiconductor absorber layer or as a kesterite semiconductor absorber layer. Methods for applying these semiconductor absorber layers are known to those skilled in the art. If a dopant is present in the contact layer, the dopant generally diffuses into the semiconductor absorber layer under the conditions for forming the latter. This is followed by initial application of first buffer layer 12 made of CdS, Zn(S,OH), or In₂S₃, for example, and subsequent application of second buffer layer 14, made of intrinsic zinc oxide, to semiconductor absorber layer 10 with the aid of thin-film deposition.

Manufacturing stage 1a of a thin-film solar module 1 according to the present invention, illustrated in FIG. 1, has been carried out in a single unit in an essentially continuous process. During the overall process period, processing may take place in a single unit. Thus, not only are costly method steps avoided, but also the risk of contamination of the intermediate product stages with oxygen, for example, is reduced.

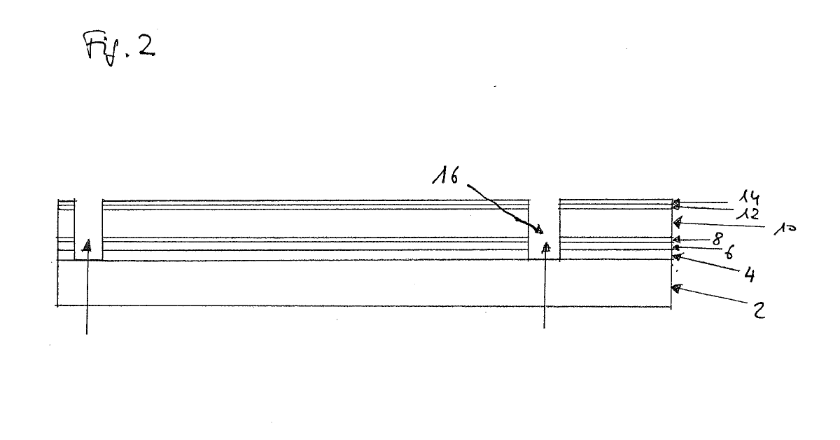

FIG. 2 shows the first structuring carried out on intermediate manufacturing stage 1a to obtain manufacturing stage 1b. With the aid of laser treatment from the bottom side of transparent substrate 2 (indicated by arrow symbols), first separating trenches 16 have been produced which ultimately determine the cell widths of the monolithically integrated series connection. In this way, all layers present above the substrate have been removed along lines over an average separating trench width of 15 μm.

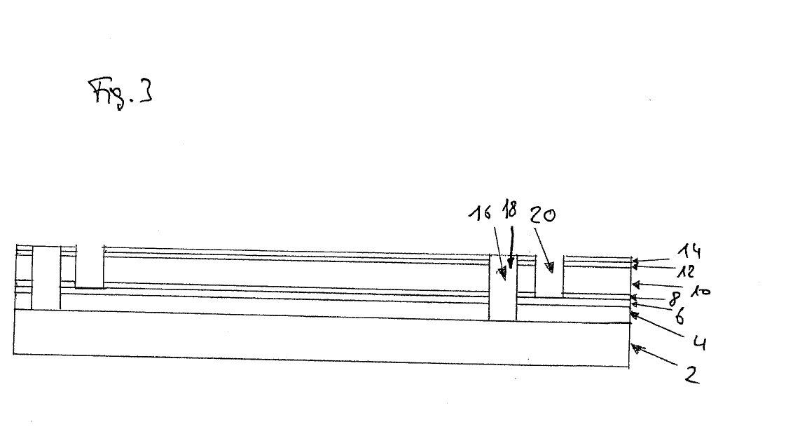

Manufacturing stage 1c depicted in FIG. 3 has separating trenches 16 which are filled with a curable insulating material 18, which in the illustrated specific embodiment extends to the top side of second buffer layer 14. In addition, with the aid of laser treatment a second structuring process has been carried out on the layer system, this time from the top side, with formation of spaced-apart second separating trenches 20. All layers have been removed, which may be over an average width of 15 μm, from second buffer layer 14, via semiconductor absorber layer 10, up to and including contact layer 8.

The steps of the first laser structuring, the filling of the first separating trenches, and the second laser structuring may be carried out in the same unit. Laborious adjustment is thus dispensed with, and instead has to be carried out only once. In addition, the first and second separating trenches may be applied at a smaller distance from one another, thus enlarging the effective surface area of the thin-film solar module.

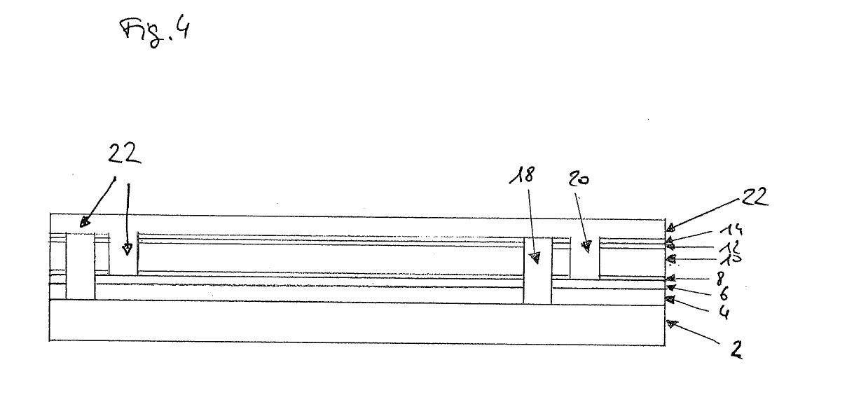

As shown in FIG. 4, a transparent, highly conductive front electrode layer 22 made of n-doped zinc oxide, for example, is applied on manufacturing stage 1c with the aid of known thin-film deposition to obtain manufacturing stage 1d. The front electrode material also penetrates into second separating trenches 20.

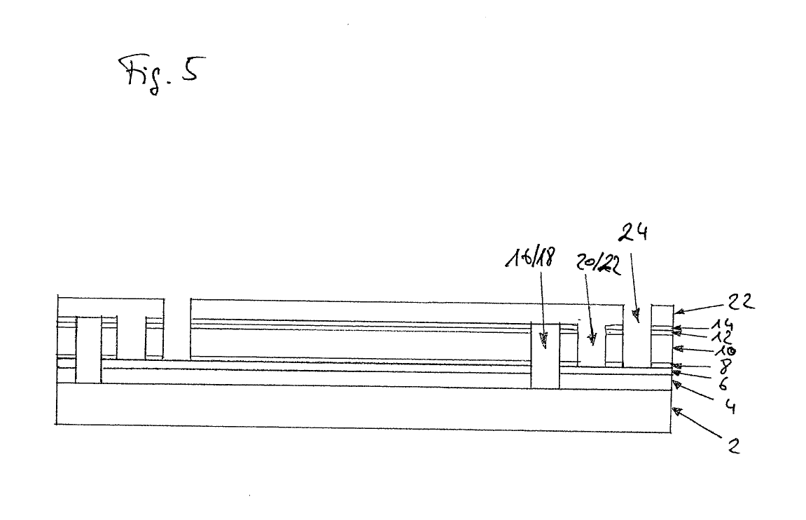

Lastly, manufacturing stage 1d undergoes a third structuring step for the purpose of defining the insulation structure in the monolithically integrated series connection, in which third separating trenches 24 which extend to barrier layer 6 are produced (see FIG. 5). This may take place with the aid of laser treatment or by mechanical methods, for example with the aid of needle scoring.

In one advantageous embodiment, in the illustrated method the target formats of the thin-film solar modules may be obtained at elevated temperatures by cutting out of the original format of the substrate after applying the metals of the semiconductor absorber layer, and prior to treating these metal layers with chalcogens.

The features of the present invention provided in the above description, in the claims, and in the drawings may be important in their various specific embodiments, alone or also in any arbitrary combination, for implementing the present invention.

1-33. (canceled)

34. A method for manufacturing photovoltaic thin-film solar modules, the method comprising:
providing a planar substrate;
applying at least one back electrode layer to the substrate;
applying at least one conductive barrier layer;
applying at least one, in particular ohmic, contact layer;
applying at least one, in particular kesterite or chalcopyrite, semiconductor absorber layer;
a first structuring step which includes removing the applied layers along spaced-apart lines with the aid of laser treatment (first laser treatment), with formation of first separating trenches which separate adjacent solar cells;
filling the first separating trenches with at least one insulating material;
a second structuring step which includes
(i) removing those layers which extend from the barrier layer in the direction of the semiconductor absorber layer or buffer layer(s) along spaced-apart lines, with formation of second separating trenches which are adjacent to corresponding first separating trenches or which abut on same,
or
(ii) chemical phase transformation and/or thermal decomposition of those layers which extend from the barrier layer in the direction of the semiconductor absorber layer or buffer layer(s) along spaced-apart lines, with formation of first linear conductive areas;
applying at least one transparent front electrode layer with filling and contacting of the second separating trenches or with contacting of the first linear conductive areas so that adjacent solar cells are connected in series; and
at least one third structuring step which includes removing the layers which extend from the barrier layer in the direction of the at least one front electrode layer along spaced-apart lines, with formation of third separating trenches which are adjacent to corresponding second separating trenches or which abut on same.

35. The method of claim 34, wherein the substrate is transparent, at least in part, to electromagnetic radiation of the first laser treatment, and/or the laser treatment in the first structuring step, in particular by laser ablation, takes place from the side facing away from the coated side of the substrate.

36. The method of claim 34, wherein the at least one contact layer contains at least one metal chalcogenide or represents a metal chalcogenide layer.

37. The method of claim 34, wherein in the second and/or third structuring step, the second or third separating trenches and the chemical phase transformation of those layers which extend from the barrier layer in the direction of the semiconductor absorber layer or buffer layer(s) are produced with the aid of laser treatment.

38. The method of claim 34, wherein at least one second separating trench, in particular all second separating trenches, is/are present in each case adjacent to and at a distance from a filled first separating trench.

39. The method of claim 34, wherein at least one third separating trench, in particular all third separating trenches, is/are separated from the corresponding filled first separating trench via the corresponding filled second separating trench or first linear conductive area.

40. The method of claim 34, wherein the back electrode contains or is formed essentially from tungsten, chromium, tantalum, niobium, vanadium, manganese, titanium, zirconium, cobalt, and/or molybdenum, preferably tungsten, titanium, and/or molybdenum, or from an alloy containing tungsten, chromium, tantalum, niobium, vanadium, manganese, titanium, zirconium, cobalt, iron, nickel, aluminum, and/or molybdenum.

41. The method of claim 34, wherein the conductive barrier layer represents a bidirectionally acting barrier layer, in particular a barrier for in particular diffusing or diffusable components, in particular dopants, which migrate out of and/or through the back electrode layer, and for diffusing or diffusable components, in particular dopants, which migrate out of and/or through the contact layer, in particular out of the semiconductor absorber layer.

42. The method of claim 34, wherein the barrier layer represents a barrier against alkali ions, in particular sodium ions, selenium or selenium compounds, sulfur or sulfur compounds, and/or metals, in particular iron, nickel, and/or metals of the semiconductor absorber layer, and/or the barrier layer contains or is formed essentially from at least one metal nitride, at least one metal silicon nitride, at least one metal carbide, and/or at least one metal boride, in particular TiN, TiSiN, TaSiN, MoN, MoSiN, TaN, WN, ZrN, and/or WSiN.

43. The method of claim 34, wherein the at least one contact layer directly adjoins the semiconductor absorber layer.

44. The method of claim 34, wherein the contact layer contains or is formed essentially from molybdenum, tantalum, niobium, and/or tungsten, and/or at least one metal chalcogenide selected from metal selenide, metal sulfide, and/or metal sulfoselenide, where the metal is Mo, W, Ta, Zr, Co, or Nb, and in particular is selected from the group composed of MoSe₂, WSe₂, WS₂, Mo(Se₁₋ₓ,Sₓ)₂, and/or W(Se₁₋ₓ,Sₓ)₂, where x assumes values from 0 to 1.

45. The method of claim 34, wherein the contact layer contains at least one dopant for the semiconductor absorber layer of the thin-film solar cell, the dopant being selected from the group composed of sodium, potassium, and lithium and/or at least one compound of these elements, preferably with oxygen, selenium, sulfur, boron, and/or halogens such as iodine or fluorine, and/or containing at least one alkali metal bronze, in particular sodium bronze and/or potassium bronze.

46. The method of claim 34, wherein the semiconductor absorber layer represents or includes a quaternary IB-IIIA-VIA chalcopyrite layer, in particular a Cu(In,Ga)Se₂-layer, a pentenary IB-IIIA-VIA chalcopyrite layer, in particular a Cu(In,Ga)(Se₁₋ₓ,Sₓ)₂-layer, or a kesterite layer, in particular a Cu₂ZnSn(Seₓ,S₁₋ₓ)₄-layer, such as a Cu₂ZnSn(Se)₄-layer or a Cu₂ZnSn(S)₄-layer, where x assumes values from 0 to 1.

47. The method of claim 34, wherein metals which are present in the contact layer or which form this contact layer are completely or partially converted into metal selenides, metal sulfides, and/or metal sulfoselenides by applying the kesterite or chalcopyrite semiconductor absorber layer to the contact layer.

48. The method of claim 34, wherein the first buffer layer is deposited dry or by wet chemical means.

49. The method of claim 34, wherein the first buffer layer contains or is formed essentially from CdS or a CdS-free layer, in particular containing or composed essentially of Zn(S,OH) or In₂S₃, and/or the second buffer layer contains or is formed essentially from intrinsically conductive zinc oxide and/or high-resistance zinc oxide.

50. The method of claim 34, wherein the first laser treatment, the second laser treatment, and/or the third laser treatment is/are carried out using laser light pulses having a pulse duration of less than 10 nanoseconds, in particular less than 100 picoseconds.

51. The method of claim 34, wherein the front electrode contains or is formed essentially from n-doped zinc oxide.

52. The method of claim 34, wherein the first, second, and third structuring steps result in or contribute to a monolithically integrated series connection of the solar cells, and in particular are designed as linear processing steps.

53. The method of claim 34, wherein the third separating trenches are formed in the third structuring step with the aid of mechanical structuring, in particular needle scoring, and/or with the aid of a third laser treatment.

54. The method of claim 34, wherein the metal of the metal chalcogenide is selected from the group composed of molybdenum, tungsten, tantalum, cobalt, zirconium, and/or niobium, and/or the chalcogen is selected from the group composed of selenium and/or sulfur.

55. The method of claim 34, wherein at least one first metal ply made of molybdenum, tantalum, tungsten, cobalt, zirconium, and/or niobium is applied to the barrier layer, and during the production of the semiconductor absorber layer, in particular the kesterite or chalcopyrite semiconductor absorber layer, this first metal ply is partially converted into a metal chalcogenide layer in a selenium- and/or sulfur-containing atmosphere, with formation of the contact layer.

56. The method of claim 34, wherein at least one first metal ply made of molybdenum, tantalum, tungsten, cobalt, zirconium, and/or niobium is applied to the barrier layer, and during the production of the semiconductor absorber layer, in particular the kesterite or chalcopyrite semiconductor absorber layer, this first metal ply is completely converted into a metal chalcogenide layer in a selenium- and/or sulfur-containing atmosphere, with formation of the contact layer.

57. The method of claim 34, wherein the barrier layer has an average thickness of at least 10 nm, in particular at least 30 nm, and preferably 250 nm or 150 nm maximum, and/or the contact layer has an average thickness of at least 5 nm and preferably not greater than 150 nm, particularly preferably not greater than 50 nm.

58. The method of claim 34, wherein the first, second, and/or third separating trench has/have an average width of not greater than 30 μm, preferably not greater than 15 μm.

59. The method of claim 34, wherein the substrate represents a glass plate having a width greater than 0.5 m, in particular greater than 2.0 m, and a length greater than 1.2 m, in particular greater than 3.0 m.

60. The method of claim 34, wherein the step of applying the semiconductor absorber layer, in particular the kesterite or chalcopyrite semiconductor absorber layer, includes the following: depositing in particular all metallic components of the semiconductor absorber layer, in particular copper, indium, and optionally gallium, for the chalcopyrite semiconductor absorber layer, and copper, zinc, and tin for the kesterite semiconductor absorber layer, on the contact layer with formation of a second metal ply, and treating this second metal ply with selenium and/or a selenium compound and optionally with sulfur and/or a sulfur compound.

61. The method of claim 60, wherein the coated substrate is separated, in particular cut, into multiple individual modules prior to the treatment of the second metal ply, in particular the copper/indium or copper/indium/gallium metal ply or the copper/zinc/tin metal ply, with selenium and/or a selenium compound and optionally with sulfur and/or a sulfur compound.

62. The method of claim 34, wherein the first and/or second metal ply is/are obtained with the aid of physical gas phase deposition, in particular including physical vapor deposition (PVD) coating, vapor deposition with the aid of an electron beam evaporator, vapor deposition with the aid of a resistance evaporator, induction evaporation, ARC evaporation, and/or cathode sputtering (sputter coating), in particular DC or RF magnetron sputtering, in each case preferably in a high vacuum, or with the aid of chemical gas phase deposition, in particular including chemical vapor deposition (CVD), low pressure CVD, and/or atmospheric pressure CVD.

63. The method of claim 34, wherein the application of the back electrode layer, the conductive barrier layer, the contact layer, and the metals of the semiconductor absorber layer, in particular Cu, In, and Ga layers for forming the chalcopyrite semiconductor absorber layer, or Cu, Zn, and Sn layers for forming the kesterite semiconductor absorber layer, takes place in a single vacuum coating unit, preferably in the continuous sputtering process.

64. A photovoltaic thin-film solar module, comprising:
a planar substrate;
at least one back electrode layer to the substrate;
at least one conductive barrier layer;
at least one contact layer;
at least one semiconductor absorber layer;
wherein the module is made from:
a first structuring step which includes removing the applied layers along spaced-apart lines with the aid of laser treatment (first laser treatment), with formation of first separating trenches which separate adjacent solar cells; wherein the first separating trenches are filled with at least one insulating material; a second structuring step which includes (i) removing those layers which extend from the barrier layer in the direction of the semiconductor absorber layer or buffer layer(s) along spaced-apart lines, with formation of second separating trenches which are adjacent to corresponding first separating trenches or which abut on same, or (ii) chemical phase transformation and/or thermal decomposition of those layers which extend from the barrier layer in the direction of the semiconductor absorber layer or buffer layer(s) along spaced-apart lines, with formation of first linear conductive areas;
applying at least one transparent front electrode layer with filling and contacting of the second separating trenches or with contacting of the first linear conductive areas so that adjacent solar cells are connected in series; and
at least one third structuring step which includes removing the layers which extend from the barrier layer in the direction of the at least one front electrode layer along spaced-apart lines, with formation of third separating trenches which are adjacent to corresponding second separating trenches or which abut on same.

65. The thin-film solar module of claim 64, further comprising:
in the following sequence, at least one substrate layer, at least one back electrode layer, at least one conductive barrier layer, at least one in particular ohmic contact layer, at least one semiconductor absorber layer which in particular directly adjoins the contact layer, in particular a chalcopyrite or kesterite semiconductor absorber layer, and optionally at least one buffer layer, in particular at least one layer (first buffer layer) which contains or is formed essentially from CdS or a CdS-free layer, in particular which contains or is formed essentially from Zn(S,OH) or In₂S₃, and/or optionally at least one layer (second buffer layer) which contains and is formed essentially from intrinsic zinc oxide and/or high-resistance zinc oxide, and at least one front electrode.

66. The thin-film solar module of claim 64, wherein the semiconductor absorber layer represents or includes a quaternary IB-IIIA-VIA chalcopyrite-layer, in particular a Cu(In,Ga)Se₂-layer, a pentenary IB-IIIA-VIA chalcopyrite-layer, in particular a Cu(In,Ga)(Se₁₋ₓ,Sₓ)₂-layer, or a kesterite layer, in particular a Cu₂ZnSn(Seₓ,S₁₋ₓ)₄-layer, such as a Cu₂ZnSn(Se)₄-layer or a Cu₂ZnSn(S)₄-layer, where x assumes values from 0 to 1.

67. The thin-film solar module of claim 64, further comprising:
at least one first buffer layer;
at least one second buffer layer;
wherein the substrate is a planar substrate,
wherein the contact layer is an ohmic contact layer,
wherein the semiconductor absorber layer includes a kesterite or chalcopyrite semiconductor absorber layer,
wherein formation of second separating trenches are adjacent to corresponding first separating trenches or which abut on same, which extend in parallel to same, and
wherein formation of third separating trenches which are adjacent to corresponding second separating trenches or which abut on same, which extend in parallel to same.

68. The method of claim 34, further comprising:
applying at least one first buffer layer;
applying at least one second buffer layer;
wherein the substrate is a planar substrate,
wherein the contact layer is an ohmic contact layer,
wherein the semiconductor absorber layer includes a kesterite or chalcopyrite semiconductor absorber layer,
wherein formation of second separating trenches are adjacent to corresponding first separating trenches or which abut on same, which extend in parallel to same, and
wherein formation of third separating trenches which are adjacent to corresponding second separating trenches or which abut on same, which extend in parallel to same.
